(19) United States
(12) Patent Application Publication
(10) Pub. No.: US 2008/0073762 A1
(43) Pub. Date: Mar. 27, 2008

(54) Semiconductor device package

(75) Inventor: Chan-Min Han, Hwaseong-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/589,721

(22) Filed: Oct. 31, 2006

(30) Foreign Application Priority Data
Sep. 21, 2006 (KR) 10-2006-0091900

(51) Int. Cl. H01L 23/495

(52) U.S. Cl. 257/675

(57) ABSTRACT

A lead-exposed semiconductor device package may include a die pad; a semiconductor chip having bonding pads mounted on the die pad; a plurality of leads arranged to be adjacent to at least one edge of the die pad and to electrically connect external to the package; a locking member provided on the plurality of leads; bonding wires electrically connecting the bonding pads with the plurality of leads; and a molding material for sealing the semiconductor chip, the die pad, the plurality of leads, the locking member, and the bonding wires. The locking member may be configured to lock the plurality of leads to the molding material.

### PRIORITY STATEMENT

This U.S. non-provisional application claims benefit of priority under 35 U.S.C. §119 of Korean Patent Application No. 2006-91900, filed Sep. 21, 2006 in the Korean Intellectual Property Office (KIPO), the entire contents of which are incorporated herein by reference.

### BACKGROUND

1. Field

Example embodiments relate to semiconductor device packages, for example, an exposed lead package and a stack type semiconductor device package using the same.

2. Description of the Related Art

There may be a trend toward smaller and/or thinner electronic devices. A semiconductor device package may be used to decrease size, decrease thickness, increase operating speed, increase performance, increase reliability, and/or provide multiple functionality.

Semiconductor device packages may be formed by a variety of processes. For example, a plurality of semiconductor chips may be formed on a semiconductor wafer. Scribe lanes may be formed on the semiconductor wafer between the plurality of semiconductor chips. The semiconductor wafer may be cut along the scribe lanes and may be divided into individual semiconductor chips. A packaging process may be performed to mount the individual semiconductor chips on a system board to complete the semiconductor device packages.

An exposed lead package (hereinafter referred to as “ELP”) may be used to satisfy one or more of the trends identified above. The ELP may include a package body formed that may expose a lower surface of a die pad, a semiconductor chip mounted on the die pad, and the leads used as an external connection terminals.

The leads in an ELP may protrude to a surface of a package molding material, rather than beyond the exterior surface of the package molding material as in a conventional lead frame package. Because the leads do not protrude beyond the exterior surface of the molding material, a area of the entire package may be reduced, and accordingly an accommodating area of a system board may be reduced. A die pad may also be exposed to a surface of a sealing resin, which may reduce the thickness of the package.

In a conventional ELP, the leads and a die pad, which may constitute a lead frame, may be sealed in a molding material and may be exposed at a lower surface of the molding material. A semiconductor chip may be mounted on the die pad of the lead frame using a bonding material. The lead frame may have a reduced thickness, for example, due to half-etching or half-stamping. The semiconductor chip may be wire-bonded to the leads, which may be spaced apart from the die pad, for example, using a conductive metal line. The semiconductor chip, the die pad and the leads may be sealed by a molding material. The molding material may be formed to externally expose lower surfaces of the die pad and the leads. The exposed surfaces of the leads may be used for electric connection terminals to the package.

Because the ELP may include the exposed leads, the ELP may be directly mountable on a system board, for example, soldered on to an external board. Thus, the manufacturing cost of the ELP may be lower than a conventional lead frame package. Further, because the lead may have a decreased length, a signal transmission path may be shortened and an overall size and/or thickness of the package may be reduced. The heat generated from the semiconductor chip during operation of the semiconductor device may be dissipated directly external to the package through the lower surface of the die pad, which may enable the heat of the semiconductor device package to be dissipated more quickly. Moreover, the die pad, on which the semiconductor chip may be mounted, may be exposed external to the package so that a ground may be formed to permit the ELP to operate in higher-frequency devices.

In a conventional ELP, the leads and a molding material may be locked using a notch structure formed on a lead frame. The notch structure may be formed on the lead frame, for example, by half-etching or half-stamping, which may reduce the thickness of the lead frame. In an ELP using such the notch structure, the leads may not be tightly attached by the molding material. Therefore, the leads and the molding material may become loose and/or separated if a physical force is applied to the ELP.

If the leads are formed in a C-shape (e.g., clamp-shape or staple-shape, [), both the upper and lower surfaces of the leads may be attached to a molding material. The leads having a sufficient thickness and hardness may not separate from a package if a physical force is applied. However, the leads that may not have a sufficient thickness and hardness may be separated from the package if a physical force is applied. If the leads is formed in an I-shape or L-shape, only the lower surface of the leads may be attached to a molding material. For this reason, the I-shaped or L-shaped leads may separate from a package more easily than the C-shaped leads if a physical force is applied.

### SUMMARY

In an example embodiment, a lead-exposed semiconductor device package may include a die pad, a semiconductor chip having bonding pads mounted on the die pad, a plurality of leads arranged to be adjacent to at least one edge of the die pad and to electrically connect external to the package, a locking member provided on the leads, bonding wires electrically connecting the bonding pads with the plurality of leads, and a molding material to seal the semiconductor chip, the die pad, the plurality of leads, the locking member, and the bonding wires. The locking member may be configured to lock the plurality of leads to the molding material.

According to an example embodiment, a stack type semiconductor device package may include a plurality of lead-exposed semiconductor device packages arranged in a stack, and bonding elements attached to the respective leads of the plurality of lead-exposed semiconductor chip packages to electrically connect the plurality of stacked lead-exposed semiconductor ship packages.

### BRIEF DESCRIPTION OF THE DRAWINGS

Example embodiments will be more clearly understood from the following detailed description taken in conjunction with the accompanying drawings.

FIG. 1A is a top plan view of a lead-exposed semiconductor device package according to an example embodiment.

FIG. 1B is a cross-sectional view taken along a line A-A′ of FIG. 1A.

FIG. 2A is a top plan view of a lead-exposed semiconductor device package according to an example embodiment.

FIG. 2B is a cross-sectional view taken along a line B-B′ of FIG. 2A.

FIG. 3 and FIG. 4 are cross-sectional views of stack type semiconductor device packages according to example embodiments.

### DESCRIPTION OF EXAMPLE EMBODIMENTS

Example embodiments will now be described more fully hereinafter with reference to the accompanying drawings, in which example embodiments are shown. Example embodiments, however, may be embodied in many different forms and should not be construed as limited to the example embodiments set forth herein. Rather, these example embodiments may be provided so that this disclosure will be thorough, and will convey the scope to those skilled in the art. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

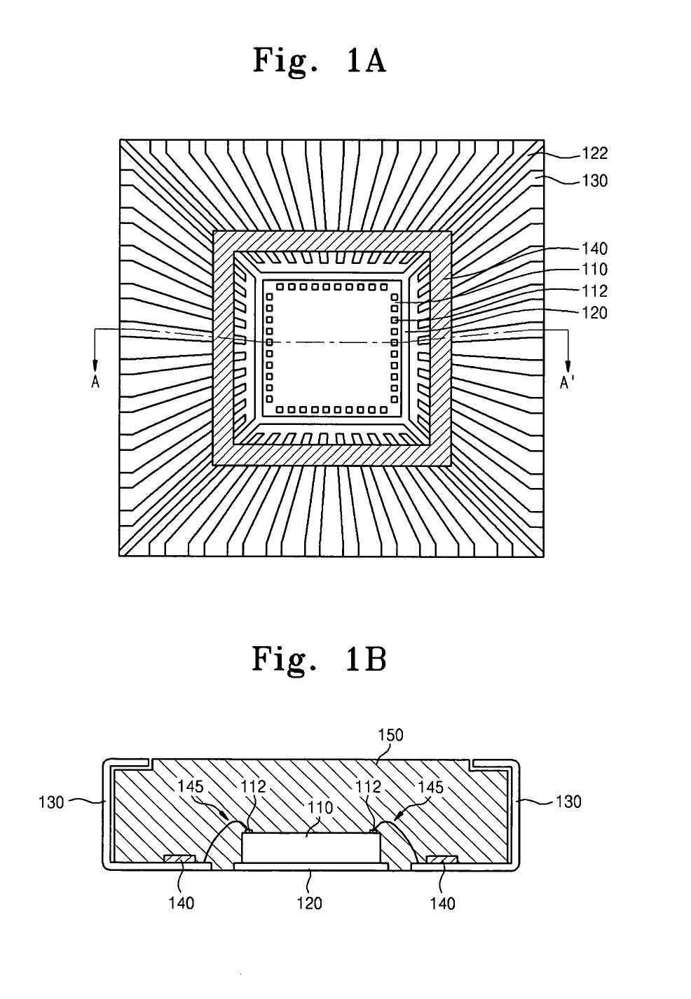

FIG. 1A is a top plan view of a lead-exposed semiconductor device package according to an example embodiment. FIG. 1B is a cross-sectional view taken along a line A-A′ of FIG. 1A.

Referring to FIG. 1A and FIG. 1B, a lead-exposed semiconductor device package may include a die pad 120, a semiconductor chip 110 having bonding pads 112 mounted on the die pad 120, leads 130 arranged to be adjacent to at least one edge of the die pad 120, a locking member 140 provided on the leads 130, and bonding wires 145 configured to electrically connect the bonding pads 112 with the corresponding leads 130. A molding material 150 may be provided to seal the semiconductor chip 110, the die pad 120, the leads 130, the locking member 140, and the bonding wires 145. Tie bars 122 may be provided to support the die pad 120.

The semiconductor chip 110 may be mounted on the die pad 120 with a bonding material (not shown). Bonding pads 112 may be provided on the upper surface of the semiconductor chip 110. In order to electrically connect the semiconductor chip 110 to an external device, the bonding pads 112 may be wire-bonded to the leads 130 using the bonding wires 145. For example, the bonding wires 145 may be made of conductive metal lines. The leads 130, which may be spaced apart from the die pad 120, may be used as external connection terminals. For example, the leads 130 may be made of copper (Cu) or alloy 42 (iron (Fe)-nickel (Ni) alloy containing about 42% nickel).

The locking member 140 may be interconnected with a plurality of the leads 130. For example, the locking member 140 may be an adhesive tape type member or a protuberance type member. The locking member 140 may be made of a non-conductive material, for example, to ensure that an electrical connection is not made between the leads 230. For example, the non-conductive material may be a polyimide adhesive tape, a silicon wafer, plastic or the like.

The molding material 150 may seal the semiconductor chip 110, the die pad 120, the leads 130, the locking member 140, and the bonding wires 145 and may expose lower surfaces of the die pad 120 and the leads 130 to the exterior of the package. The molding material 150 may be a molding resin, for example, an epoxy molding compound (EMC). The exposed surfaces of the leads 130 may be used to electrically connect to an external device to the package. The semiconductor device package may be mounted on a system board, for example, an external board having an accommodating area similar in size to the semiconductor device package.

The molding material 150 may seal the lower, upper, and side surfaces of the locking member 140. If the locking member 140 is an adhesive tape type member, the leads 130 may be adhered to the locking member 140 due to the adhesive property of the locking member 140, and the locking member 140 may be sealed within or partially sealed within the molding material 150 to lock the leads 130 to the molding material 150. If the locking member 140 is a protuberance type member, the locking member 140 may be bonded to the surfaces of the leads 130, for example, with an adhesive, and the locking member 140 may be sealed within or partially sealed within the molding material 150 to lock the leads 130 to the molding material 150. If a physical force is applied to the package, the locking member 140 may act as a latch between the molding material 150 and the leads 130 to act against the physical force.

As described above, the leads 130 and the molding material 150 may be locked by the locking member 140. Thus, the leads 130 may not be separated from the package if a physical force is applied to the package.

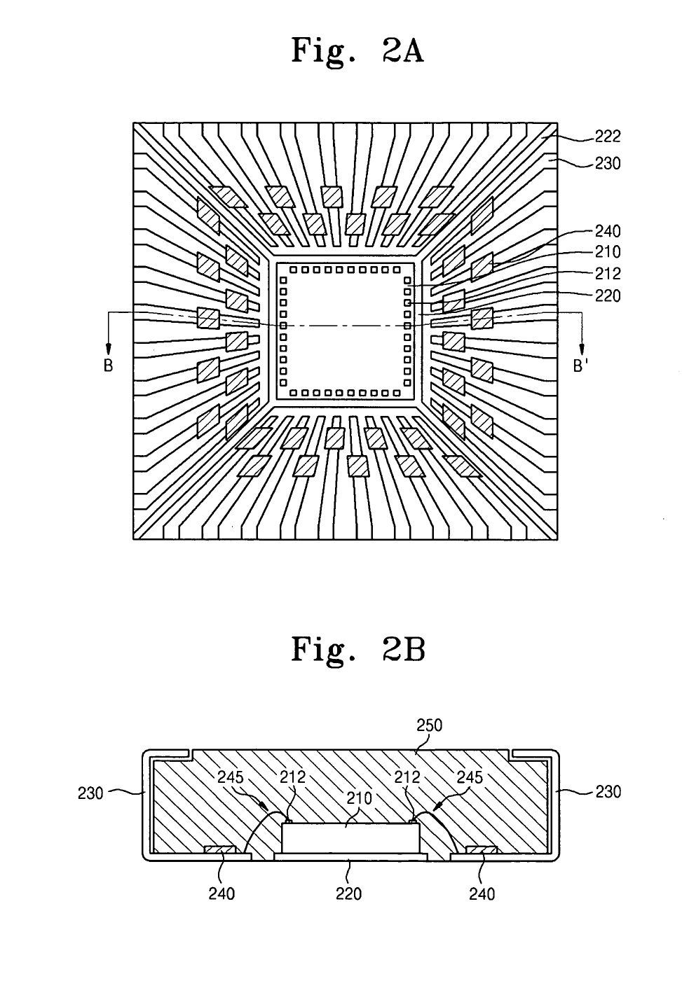

FIG. 2A is a top plan view of a lead-exposed semiconductor device package according to an example embodiment. FIG. 2B is a cross-sectional view taken along a line B-B′ of FIG. 2A.

Referring to FIG. 2A and FIG. 2B, a lead-exposed semiconductor device package may include a die pad 220, a semiconductor chip 210 having bonding pads 212 mounted on the die pad 220, leads 230 arranged to be adjacent to at least one edge of the die pad 220, locking members 240 provided on the leads 230, and bonding wires 245 configured to electrically connect the bonding pads 212 with the corresponding leads 230. A molding material 250 may be provided to seal the semiconductor chip 210, the die pad 220, the leads 230, the locking member 240, and the bonding wires 245. Tie bars 222 may be provided to support the die pad 220.

The semiconductor chip 210 may be mounted on the die pad 220 with a bonding material. Bonding pads 212 may be provided on the upper surface of the semiconductor chip 210. In order to electrically connect the semiconductor chip 210 to a device external to the package, the bonding pads 212 may be wire-bonded to the leads 230 using the bonding wires 245. For example, the bonding wires 245 may be made of conductive metal lines. The leads 230, which may be spaced apart from the die pad 220, may be used as external connection terminals. For example, the leads 230 may be made of copper (Cu) or alloy 42 (iron (Fe)-nickel (Ni) alloy containing 42% nickel).

The locking members 240 may be provided on each lead 230 individually and may be isolated from the other leads 230. The locking members 240 may be adhesive tape type members or protuberance type members. Each of the locking members 240 may be wider than the corresponding lead 230 on which it may be provided. The locking members 240 may be made of a non-conductive material or conductive material. However, a non-conductive material may be used to ensure that an electrical connection is not made between the leads 230. For example, the non-conductive material may be a polyimide adhesive tape, a silicon wafer, plastic or the like.

The molding material 250 may seal the semiconductor chip 210, the die pad 220, the leads 230, the locking members 240, and the bonding wires 245 and may expose lower surfaces of the die pad 220 and the leads 230 to the exterior of the package. The molding material 250 may be a molding resin, for example, an epoxy molding compound (EMC). The exposed surfaces of the leads 230 may be used for an electrical connection to an external device to the package. The semiconductor device package may be mounted on a system board, for example, an external board having an accommodating area similar in size to the semiconductor device package.

The molding material 250 may seal the lower, upper, and side surfaces of the locking members 240. If the locking members 240 are adhesive tape type members, the leads 230 may be adhered to the locking members 240 due to the adhesive property of the locking members 240, and the locking members 240 may be sealed within or partially within the molding material 250 to lock the leads 230 to the molding material 250. If the locking members 240 are protuberance type members, the locking members 240 may be bonded to the surfaces of the leads 230, for example, with an adhesive, and the locking members 240 may be sealed within or partially within the molding material 250 to lock the leads 230 to the molding material 250. If a physical force is applied to the package, the locking members 240 may act as latches between the molding material 250 and the leads 230 to act against the physical force.

As described above, the leads 230 and the molding material 250 may be locked by the locking members 240. Thus, the leads 230 may not be separated from the package if a physical force is applied to the package.

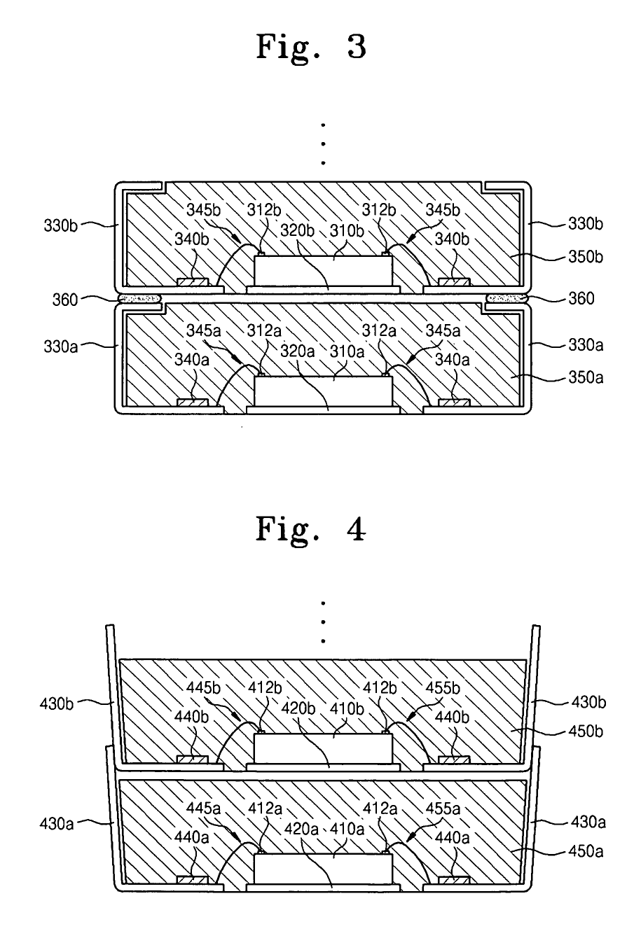

FIG. 3 and FIG. 4 are cross-sectional views of stack type semiconductor device packages according to example embodiments.

Referring to FIG. 3, a stack type semiconductor device package may include a plurality of lead-exposed semiconductor device packages that may be arranged in a stack. The plurality of stacked lead-exposed semiconductor device packages may be connected by bonding elements 360. Each of the plurality of lead-exposed semiconductor device packages may include die pads 320a, 320b; semiconductor chips 310a, 310b having bonding pads 312a, 312b mounted respectively on the die pads 320a, 320b; leads 330a, 330b arranged to be adjacent to at least one edge of the die pads 320a, 320b; locking members 340a, 340b provided on the leads 330a, 330b; and bonding wires 345a, 345b configured to electrically connect the bonding pads 312a, 312b with the corresponding leads 330a, 330b. Molding materials 350a, 350b may be provided to seal the semiconductor chips 310a, 310b, the die pads 320a, 320b, the leads 330a, 330b, the locking members 340a, 340b, and the bonding wires 345a, 345b. The bonding elements 360 may be attached to the respective leads 330a, 330b of the plurality of stacked lead-exposed semiconductor device packages and may offer an electrical connection between the stacked lead-exposed semiconductor device packages. For example, the bonding elements 360 may be a solder material.

The leads 330a, 330b, which may be spaced apart from the die pads 320a, 320b, may be used as external connection terminals. For example, each of the leads 330a, 330b may have a C-shape (e.g., clamp-shape or staple-shape, [) and be made of copper (Cu) or alloy 42 (iron (Fe)-nickel (Ni) alloy containing 42% nickel).

The locking members 340a, 340b may be interconnected with a plurality of the leads 330a, 330b or may be provided on each of the leads 330a, 330b individually and isolated from the other leads 330a, 330b. The locking members 340a, 340b may be adhesive tape type members or protuberance type members. If the locking members 340a, 340b are interconnected with a plurality of the leads 330a, 330b, each of the locking members 340a, 340b may be made of a non-conductive material to ensure that an electrical connection is not made between the plurality of leads 340a, 340b. If the locking members 340a, 340b are provided on the leads 330a, 330b individually, each of the locking members 340a, 340b may be made of a conductive material or non-conductive material. However, a non-conductive material may be used to ensure an electrical connection is not made between the leads 330a, 330b. For example, the non-conductive material may be a polyimide adhesive tape, a silicon wafer, plastic or the like.

The molding materials 350a, 350b may seal the semiconductor chips 310a, 310b, the die pads 320a, 320b, the leads 330a, 330b, the locking members 340a, 340b, and the bonding wires 345a, 345b and may expose lower surfaces of the die pads 320a, 320b and the leads 330a, 330b to the exterior of the package. The molding materials 350a, 350b may be molding resin, for example, an epoxy molding compound (EMC). The exposed surfaces of the leads 330a, 330b may be used to electrically connect to an external device to the package or may electrically connect between the stacked lead-exposed semiconductor device packages through the bonding elements 360. The stack type semiconductor device package may be mounted on a system board, for example, an external board having an accommodation area similar in size to the stack type semiconductor device package.

The molding materials 350a, 350b may seal the lower, upper, and side surfaces of the locking members 340a, 340b. If the locking members 340a, 340b are adhesive type members, the locking members 340a, 340b may be adhered to the leads 330a, 330b due to the adhesive property of the locking members 340a, 340b, and the locking members 340a, 340b may be sealed within or partially sealed within the molding materials 350a, 350b to lock the leads 330a, 330b to the molding materials 350a, 350b. If the locking members 340a, 340b are protuberance type members, the locking members 340a, 340b may be bonded to the leads 330a, 330b, for example, with an adhesive, and the locking members 340a, 340b may be sealed within or partially sealed within the molding materials 350a, 350b to lock the leads 330a, 330b to the molding materials 350a, 350b. If a physical force is applied to the package, the locking members 340a, 340b may act as a latch between each of the molding materials 350a, 350b and each of the leads 330a, 330b to act against the physical force.

As described above, the leads 330a, 330b and the molding materials 350a, 350b may be locked by the locking members 340a, 340b. Thus, the leads 330a, 330b may not be separated from the package if a physical force is applied to the package.

Referring to FIG. 4, a stack type semiconductor device package may include a plurality of lead-exposed semiconductor device packages that may be arranged in a stack. The plurality of stacked lead-exposed semiconductor device packages that may be connected by bonding elements (not shown). Each of the plurality of lead-exposed semiconductor device packages may include die pads 420a, 420b; semiconductor chips 410a, 410b having bonding pads 412a, 412b mounted on the die pads 420a, 420b; leads 430a, 430b arranged to be adjacent to at least one edge of the die pads 420a, 420b; locking members 440a, 440b provided on the leads 430a, 430b; and bonding wires 445a, 445b may be configured to electrically connect the bonding pads 412a, 412b with the corresponding leads 430a, 430b. Molding materials 450a, 450b may be provided to seal the semiconductor chips 410a, 410b, the die pads 420a, 420b, the leads 430a, 430b, the locking members 440a, 440b, and the bonding wires 445a, 445b. The bonding elements (not shown) may be attached to the respective leads 430a, 430b of the plurality of stacked lead-exposed semiconductor chip packages and may offer an electrical connection between the stacked lead-exposed semiconductor chip packages. For example, the bonding elements may be a solder material.

The leads 430a, 430b, which may be spaced apart from the die pads 420a, 420b, may be used as external connection terminals. For example, each of the leads 430a, 430b may have an I-shape or L-shape and be made of copper (Cu) or alloy 42 (iron (Fe)-nickel (Ni) alloy containing 42% nickel).

The locking members 440a, 440b may be interconnected with a plurality of the leads 430a, 430b or may be provided on each of the leads 430a, 430b individually and isolated from the other leads 430a, 430b. The locking members 440a, 440bmay be adhesive tape type members or protuberance type members. If the locking members 440a, 440b are interconnected with a plurality of the leads 430a, 430b, each of the locking members 440a, 440b may be made of a non-conductive material to ensure that an electrical connection is not made between the plurality of leads 430a, 430b. If the locking members 440a, 440b are provided on the leads 430a, 430b individually, each of the locking members 440a, 440b may be made of a conductive material or non-conductive material. However, a non-conductive material may be used to ensure an electrical connection is not made between the leads 430a, 430b. For example, the non-conductive material may be a polyimide adhesive tape, a silicon wafer, plastic or the like.

The molding materials 450a, 450b may seal the semiconductor chips 410a, 410b, the die pads 420a, 420b, the leads 430a, 430b, the locking members 440a, 440b, and the bonding wires 445a, 445b and may expose lower surfaces of the die pads 420a, 420band the leads 430a, 430b to the exterior of the package. The molding materials 430a, 430b may be a molding resin, for example, an epoxy molding compound (EMC). The exposed surfaces of the leads 430a, 430b may be used to electrically connect to a device external to the package or may electrically connect between stacked lead-exposed semiconductor device packages through the bonding elements (not shown). The stack type semiconductor device package may be mounted on a system board, for example, an external board having an accommodation area similar in size to the stack type semiconductor device package.

The molding materials 450a, 450b may seal the lower, upper, and side surfaces of the locking members 440a, 440b. If the locking members 440a, 440b are adhesive type members, the locking members 440a, 440b may be adhered to the leads 430a, 430b due to the adhesive property of the locking members 440a, 440b, and the locking members 440a, 440b may be sealed within or partially sealed within the molding materials 450a, 450b to lock of the leads 430a, 430b to the molding materials 450a, 450b. If the locking members 440a, 440b are protuberance type members, the locking members 440a, 440b may be bonded to a surface of the leads 430a, 430b, for example, with an adhesive, and the locking members 440a, 440b may be sealed within or partially sealed within the molding materials 450a, 450b to lock the leads 430a, 430b to the molding materials 450a, 450b. If a physical force is applied to the package, the locking members 440a, 440b may act as a latch between each of the molding materials 450a, 450b and each of the leads 430a, 430b to act against the physical force.

As described above, the leads 430a, 430b and the molding materials 450a, 450b may be locked by the locking members 440a, 440b. Thus, the leads 430a, 430b may not be separated from the package if a physical force is applied to the package.

According to example embodiments, a locking member may be provided to lock the leads to a molding material of a lead-exposed package. The locking member may prevent the leads from separating from the package if a physical force is applied, for example, externally. Therefore, a semiconductor device package may have higher reliability.

According to example embodiments, locking members may be provided to lock the leads and the molding materials of a plurality of lead-exposed packages. The locking members may prevent the leads from separating from the packages if a physical force is applied, for example, externally. Therefore, a stack type semiconductor device package may have higher reliability.

Although example embodiments have been described in connection with the accompanying drawings, it is not limited thereto. It will be apparent to those skilled in the art that various substitutions, modifications and changes may be made without departing from the scope and spirit of the example embodiments.

What is claimed is:

1. A lead-exposed semiconductor device package comprising:
a die pad;
a semiconductor chip having bonding pads mounted on the die pad;
a plurality of leads spaced apart from at least one edge of the die pad and providing an electrical connection external to the package;
a locking member provided on the plurality of leads;
bonding wires electrically connecting the bonding pads with the plurality of leads; and
a molding material for sealing the semiconductor chip, the die pad, the plurality of leads, the locking member, and the bonding wires,
wherein the locking member is configured to lock the plurality of leads to the molding material.

2. The package as set forth in claim 1, wherein the plurality of leads are formed from at least one of copper or alloy 42.

3. The package as set forth in claim 1, wherein the locking member is interconnected with the plurality of leads.

4. The package as set forth in claim 3, wherein the locking member is formed from a non-conductive material.

5. The package as set forth in claim 3, wherein the locking member is an adhesive tape type member or a protuberance type member.

6. The package as set forth in claim 1, wherein the locking member is a plurality of locking members, and wherein the plurality of locking members is provided on each of the plurality of leads individually and isolated from each of the other plurality of leads.

7. The package as set forth in claim 6, wherein each locking member is wider than the corresponding lead on which the locking member is provided.

8. The package as set forth in claim 6, wherein the plurality of locking members are adhesive tape type members or protuberance type members.

9. The package as set forth in claim 1, wherein the molding material is an epoxy molding compound.

10. A stack type semiconductor device package comprising:
a plurality of the lead-exposed semiconductor device packages of claim 1 arranged in a stack; and
bonding elements attached to the respective leads of the plurality of lead-exposed semiconductor chip packages to electrically connect the plurality of stacked lead-exposed semiconductor chip packages.

11. The package as set forth in claim 10, wherein each of the plurality of leads is C-shaped ([), I-shaped, or L-shaped.

12. The package as set forth in claim 11, wherein each of the plurality of leads is formed from at least one of copper or alloy 42.

13. The package as set forth in claim 10, wherein the locking member of the lead-exposed semiconductor device packages is interconnected with the plurality of leads.

14. The package as set forth in claim 13, wherein the locking member of the lead-exposed semiconductor device packages is formed from a non-conductive material.

15. The package as set forth in claim 13, wherein the locking member is an adhesive tape type member or a protuberance type member.

16. The package as set forth in claim 10, wherein the locking member of the lead-exposed semiconductor device packages is a plurality of locking members, and wherein the plurality of locking members is provided on each of the plurality of leads individually and isolated from each of the other plurality of leads.

17. The package as set forth in claim 16, wherein each locking member is wider than the corresponding lead on which the locking member is provided.

18. The package as set forth in claim 16, wherein the plurality of locking members are adhesive tape type members or protuberance type members.

19. The package as set forth in claim 10, wherein the molding material is an epoxy molding compound.

20. The package as set forth in claim 10, wherein the bonding element is a solder material.
